(19) United States
(12) Patent Application Publication
(10) Pub. No.: US 2011/0101510 A1
(43) Pub. Date: May 5, 2011

(54) BOARD ON CHIP PACKAGE SUBSTRATE AND MANUFACTURING METHOD THEREOF

(76) Inventors: Kyung-Ro YOON, Yoosung-gu (KR); Young-Mi Lee, Daeduck-gu (KR); Young-Hwan Shin, Yoosung-gu (KR)

(21) Appl. No.: 12/912,202

(22) Filed: Oct. 26, 2010

(30) Foreign Application Priority Data
Oct. 26, 2009 (KR) 10-2009-0101907

(51) Int. Cl. H01L 23/495; H01L 21/58

(52) U.S. Cl. 257/668; 438/125; 257/E23.033; 257/E21.505

(57) ABSTRACT

A single-layer board on chip package substrate and a manufacturing method thereof are disclosed. In accordance with an embodiment of the present invention, the substrate includes an insulator, a first pad and a second pad, which are provided on an upper surface of the insulator, a through-hole, which is formed in the insulator such that a lower surface of the first pad is exposed, and a solder resist layer, which is formed on the upper surface of the insulator such that at least a portion of the second pad is exposed.

### CROSS-REFERENCE TO RELATED APPLICATIONS

This application claims the benefit of Korean Patent Application No. 10-2009-0101907, filed with the Korean Intellectual Property Office on Oct. 26, 2009, the disclosure of which is incorporated herein by reference in its entirety.

### BACKGROUND

1. Technical Field

The present invention is related to a single-layer board on chip package substrate and a manufacturing method thereof.

2. Description of the Related Art

Compared to the conventional electronic devices, the latest electronic devices have become increasingly smaller. For this, there has been a demand for smaller-size, higher-performance semiconductor chip packages. Used for semiconductor chip packages to cope with this current trend is a multi chip package, in which a plurality of semiconductor chips are stacked vertically or a plurality of semiconductor chips arranged in a flat surface are embedded, or a board on chip package, in which a semiconductor chip is directly adhered to the board and sealed to reduce the overall size.

The board on chip (BOC) is receiving attention as a next generation high-speed semiconductor substrate that is suitable for high-speed DRAM, such as DDR2, because a bare die itself can be placed directly on a substrate to minimize thermal and electrical losses caused by the high-speed of DRAM, unlike the conventional method of mounting a semiconductor on a substrate by using a lead frame. The currently available storage capacities of DRAM are 128 MB, 256 MB, 512 MB, 1 GB and 2 GB, and are rapidly increasing. In order to cope with the rapidly increasing capacities of DRAM, it is required to reduce the thickness of a substrate to minimize the electrical loss and secure the product reliability. The conventional board on chip package has a hole in the center of the substrate in order to connect the semiconductor chip, and wire bonding is implemented by the hole.

Even in this conventional board on chip package, the increased number of input/output terminals for higher-integration has become a problem, and cost-saving measures have been sought in the manufacture of the printed circuit board.

### SUMMARY

The present invention provides a single-layer board on chip package substrate and a method of manufacturing the same that can implement higher-density and save the production cost.

An aspect of the present invention provides a single-layer board on chip package substrate that includes an insulator, a first pad and a second pad, which are provided on an upper surface of the insulator, a through-hole, which is formed in the insulator such that a lower surface of the first pad is exposed, and a solder resist layer, which is formed on the upper surface of the insulator such that at least a portion of the second pad is exposed.

The single-layer board on chip package substrate can further include a first surface treatment layer, which is coated on a surface of the first pad and in which the first pad is exposed through the through-hole, and a second surface treatment layer, which is coated on a surface of the second pad. The first surface treatment layer can be a conductive paste filling a portion of the through-hole.

The single-layer board on chip package substrate can further include a solder ball, which is connected to a lower surface of the first pad, and an electronic component, which is mounted on an upper side of the insulator by being connected to the second pad by a flip-chip method.

Another aspect of the present invention provides a method of manufacturing a single-layer board on chip package substrate. The method includes forming a through-hole in an insulator, stacking a metal layer on an upper surface of the insulator, forming a first pad and a second pad by selectively etching the metal layer, in which the first pad covers the through-hole, and forming a solder resist layer on the upper surface of the insulator in such a way that at least a portion of the second pad is exposed.

The method can further include coating a first surface treatment layer on a surface of the first pad, in which the first pad is exposed through the through-hole, and coating a second surface treatment layer on a surface of the second pad.

The coating of the first surface treatment layer can include injecting a conductive paste into the through-hole so as to fill a portion of the through-hole.

The method can further include adhering a solder ball in such a way that the solder ball is connected to a lower surface of the first pad and mounting an electronic component on an upper side of the insulator in such a way that the electronic component is connected to the second pad by a flip-chip method.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a cross-sectional view of a package substrate in accordance with an embodiment of the present invention.

FIG. 2 is a cross-sectional view illustrating an electronic component mounted on the package substrate of FIG. 1.

FIG. 3 is a flow chart illustrating a method of manufacturing a package substrate in accordance with an embodiment of the present invention.

FIGS. 4 to 10 illustrate each respective process of manufacturing a package substrate in accordance with an embodiment of the present invention.

### DETAILED DESCRIPTION

As the invention allows for various changes and numerous embodiments, a particular embodiment will be illustrated in the drawings and described in detail in the written description. However, this is not intended to limit the present invention to a particular mode of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

While such terms as “first” and “second,” etc., may be used to describe various components, such components must not be limited to the above terms. The above terms are used only to distinguish one component from another. A board on chip package substrate and a manufacturing method thereof according to a certain embodiment of the present invention will be described below in more detail with reference to the accompanying drawings. Those components that are the same or are in correspondence are rendered the same reference numeral regardless of the figure number, and redundant descriptions are omitted.

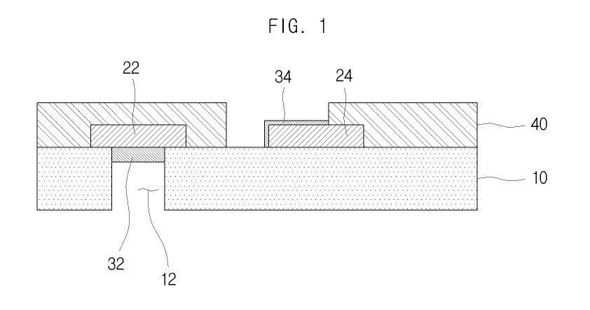

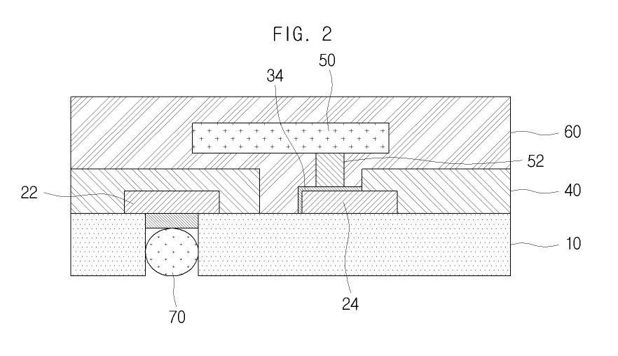

FIG. 1 is a cross-sectional view of a package substrate in accordance with an embodiment of the present invention, and FIG. 2 is a cross-sectional view illustrating an electronic component mounted on the package substrate of FIG. 1. Illustrated in FIGS. 1 and 2 are an insulator 10, a through-hole 12, a first pad 22, a second pad 24, a metal layer 30, a first surface treatment layer 32, a second surface treatment layer 34, a solder resist layer 40, an electronic component 50, a molding material 60 and a solder ball 70.

The first pad 22, the second pad 24 and other wiring patterns (not shown) are formed on an upper surface of the insulator 10. The first pad 22 can function as an input/output terminal that can transceiver a signal with a mother board (not shown) through the solder ball 70, and the second pad 24 can function as an input/output terminal that can transceiver a signal with the electronic component 50 mounted on the insulator 10.

The through-hole 12 is formed in the insulator 10. Here, the through-hole 12 is formed to correspond with the location of the first pad 22 such that a lower surface of the first pad 22 can be exposed through the through-hole 12. The exposed lower surface of the first pad 22 is coupled to the solder ball 70, allowing the first pad 22 to transceiver a signal with a mother board.

Through this structure, the portion where the solder ball 70 is coupled can be defined by the insulator 10 itself in the package substrate of the present embodiment, while in a conventional package substrate, the portion where the solder ball 70 is coupled is defined by an additional solder mask. As a result, it becomes possible to omit an additional process of forming a solder mask.

The solder resist layer 40 is coated on an upper surface of the insulator 10. The solder resist layer 40 functions to protect a wiring pattern that is formed on the upper surface of the insulator 10. Here, the second pad 24, which is an input/output terminal for transceiving a signal with the electronic component 50, is exposed. As the first pad 22 is coupled to the solder ball 70 through its lower surface, the upper surface is covered by the solder resist layer 40. The upper surface of the second pad 24 can be either completely exposed or partially exposed, as illustrated in FIG. 1.

The surface treatment layers 32 and 34 can be coated on the exposed surfaces of the first pad 22 and the second pad 24, respectively. By forming the surface treatment layers 32 and 34, the first pad 22 and the second pad 24 can be prevented from being corroded while being stored or transported.

Used for the surface treatment layers 32 and 34 can be OSP, nickel/gold (Ni/Au), tin and the like. Here, it is possible that a conductive paste that fills a portion of the through-hole 12 is used as the surface treatment layer 32 that is coated on the surface of the first pad 22. If the conductive paste fills a portion of the through-hole 12, the depth of the through-hole 12 to which the solder ball 70 has to be inserted in order to be connected with the first pad 22 can be smaller, and thus the solder ball 70 and the first pad 22 can be connected to each other more easily. However, it shall be apparent that the present invention is not limited to this example.

The solder ball 70 is connected to the lower surface of the first pad 22. Since the lower surface of the first pad 22 is exposed through the through-hole 12 that penetrates through the insulator 10, a portion of the solder ball 70 can be connected to the first pad 22 by being inserted into the through-hole 12, as illustrated in FIG. 2. If the first surface treatment layer 32 having conductivity is coated on the lower surface of the first pad 22, the first pad 22 and the solder ball 70 can be connected to each other through the first surface treatment layer 32. If the first surface treatment layer 32 is not provided or a non-conductive material, such as OSP, is used for the first surface treatment layer 32, the first pad 22 and the solder ball 70 can be directly connected to each other.

As described earlier, unlike the conventional package substrate in which a portion where the solder ball 70 is coupled is defined by a solder mask, the portion where the solder ball 70 is coupled in the package substrate of the present embodiment is defined by the insulator 10 itself.

Meanwhile, the electronic component 50 is mounted on an upper side of the insulator 10. Here, it is possible that a flip-chip method is used to connect the electronic component 50 to the second pad 24. That is, the electronic component 50 is not mounted by a face-up method to be connected to the second pad 24 through a wire but mounted by a face-down method to be connected to the second pad 24 through a connection bump 52. With this flip-chip connection, a greater number of input/output paths can be obtained to provide an advantageous structure for higher-density. This, however, is by no means to restrict the present invention to this embodiment, and shall be apparent that the second pad 24 and the electronic component 50 can be connected to each other through the wire mentioned above.

The electronic component 50 mounted on the upper side of the insulator 10 is covered by the molding material 60 and protected from the outside.

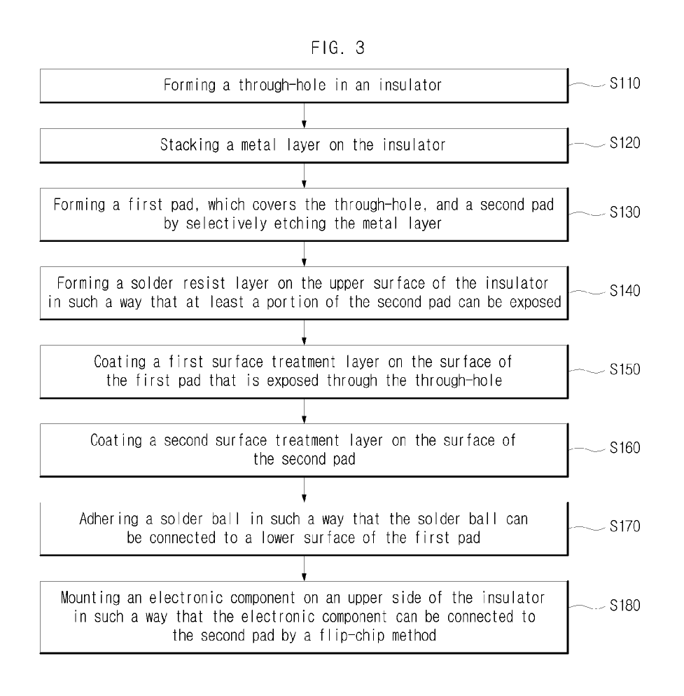

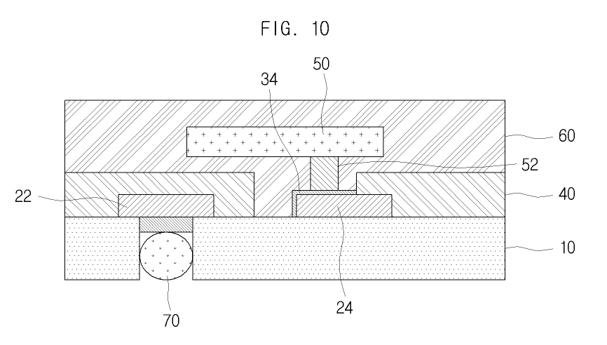

Hitherto, the structure of a package substrate in accordance with an embodiment of the present invention has been described. Hereinafter, a method of manufacturing the same will be described with reference to FIGS. 3 to 10.

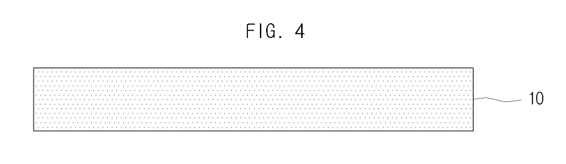

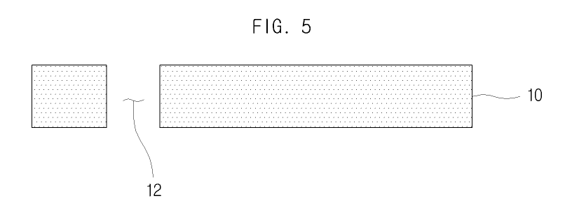

First, as illustrated in FIG. 4, an insulator 10 is prepared, and then, as illustrated in FIG. 5, a through-hole 12 is formed in the insulator 10 (S110). For the insulator 10, prepreg and the like can be used. However, it shall be evidently understood that the present invention is not limited to this example, and any other material can be substituted for the insulator 10 as long as it is an insulating material that can be used for a printed circuit board. In order to process a hole in the insulator 10, a mechanical drill or laser drill can be used.

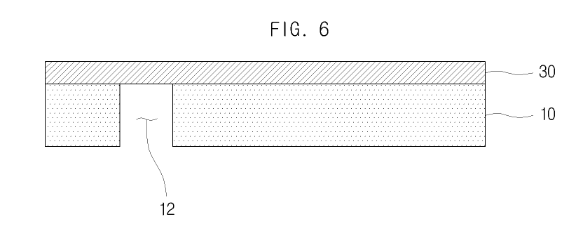

Then, as illustrated in FIG. 6, a metal layer 30 is stacked on an upper surface of the insulator 10 (S120). For the metal layer 30, a copper thin film can be used. However, it shall be evidently understood that any conductive metallic material, for example, aluminum (Al), other than the copper thin film can be used for the metal layer 30. By the stacked metal layer 30, the upper side of the through-hole 12 is covered.

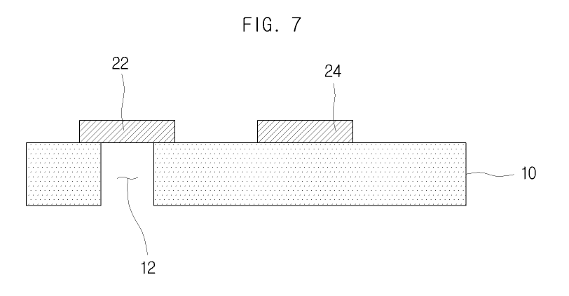

Next, as illustrated in FIG. 7, a first pad 22, which covers the through-hole 12, and a second pad 24 are formed by selectively etching the metal layer 30 (S130). In order to form the first pad 22 and the second pad 24, a patterned etching resist (not shown) can be formed on an upper surface of the metal layer 30, and then an etching solution can be provided to the metal layer 30. The etching resist (not shown) can be formed by exposing and developing a photo-sensitive resin. The upper side of the through-hole 12 is covered by the first pad 22.

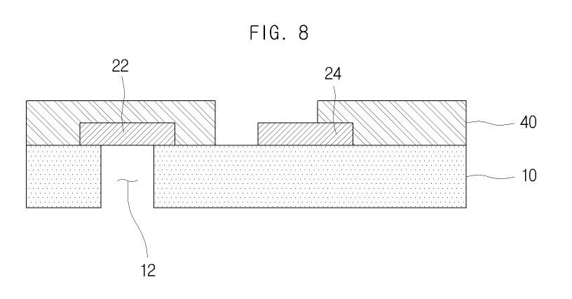

Next, as illustrated in FIG. 8, a solder resist layer 40 is formed on the upper surface of the insulator 10 in such a way that at least a portion of the second pad 24 can be exposed (S140). For this, solder resist ink can be coated on the upper surface of the insulator 10, and then a portion of the solder resist ink can be opened in such a way that the second pad 24 can be partially or completely exposed.

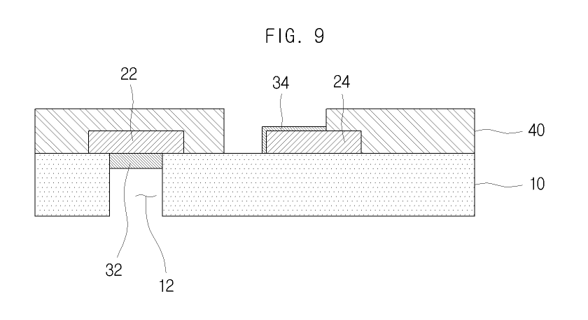

Next, as illustrated in FIG. 9, a first surface treatment layer 32 is coated on the surface of the first pad 22 that is exposed through the through-hole 12 (S150), and a second surface treatment layer 34 is coated on the surface of the second pad 24 (S160). It shall be apparent that although coating the first surface treatment layer 32 and coating the second surface treatment layer 34 can be successively performed, they can be performed at the same time as well.

Used for the surface treatment layers can be OSP, nikel/gold (Ni/Au), tin and the like. Here, it is possible that a conductive paste that fills a portion of the through-hole 12 is used as the first surface treatment layer 32 that is coated on the surface of the first pad 22. If the conductive paste fills a portion of the through-hole 12, the depth of the through-hole 12 to which a solder ball 70 has to be inserted in order to be connected with the first pad 22 can be smaller, and thus the solder ball 70 and the first pad 22 can be connected to each other more easily. However, it shall be apparent that the present invention is not limited to this example.

Next, the solder ball 70 is coupled in such a way that the solder ball 70 can be connected to a lower surface of the first pad 22 (S170). Since the lower surface of the first pad 22 is exposed through the through-hole 12 that penetrates through the insulator 10, a portion of the solder ball 70 can be connected to the first pad 22 by being inserted into the through-hole 12. If the first surface treatment layer 32 having conductivity is coated on the lower surface of the first pad 22, the first pad 22 and the solder ball 70 can be connected to each other through the first surface treatment layer 32. If the first surface treatment layer 32 is not provided or a non-conductive material, such as OSP, is used for the first surface treatment layer 32, the first pad 22 and the solder ball 70 can be directly connected to each other.

Next, an electronic component 50 is mounted on an upper side of the insulator 10 in such a way that the electronic component 50 can be connected to the second pad 24 by a flip-chip method (S180). That is, the electronic component 50 is not mounted by a face-up method to be connected to the second pad 24 through a wire but mounted by a face-down method to be connected to the second pad 24 through a connection bump 52. With this flip-chip connection, a greater number of input/output paths can be obtained to provide an advantageous structure for higher-density. This, however, is by no means to restrict the present invention to this embodiment, and shall be apparent that the second pad 24 and the electronic component 50 can be connected to each other through the wire mentioned above.

The electronic component 50 mounted on the upper side of the insulator 10 is covered by the molding material 60 and protected from the outside.

By utilizing certain embodiments of the present invention as set forth above, higher-density can be implemented, and the production cost can be saved.

While the spirit of the present invention has been described in detail with reference to a particular embodiment, the embodiment is for illustrative purposes only and shall not limit the present invention. It is to be appreciated that those skilled in the art can change or modify the embodiment without departing from the scope and spirit of the present invention.

As such, many embodiments other than that set forth above can be found in the appended claims.

What is claimed is:

1. A single-layer board on chip package substrate comprising:
an insulator;
a first pad and a second pad provided on an upper surface of the insulator;
a through-hole formed in the insulator such that a lower surface of the first pad is exposed; and
a solder resist layer formed on the upper surface of the insulator such that at least a portion of the second pad is exposed.

2. The single-layer board on chip package substrate of claim 1, further comprising:
a first surface treatment layer coated on a surface of the first pad, the first pad being exposed through the through-hole; and
a second surface treatment layer coated on a surface of the second pad.

3. The single-layer board on chip package substrate of claim 2, wherein the first surface treatment layer is a conductive paste filling a portion of the through-hole.

4. The single-layer board on chip package substrate of claim 1, further comprising:
a solder ball connected to a lower surface of the first pad; and
an electronic component mounted on an upper side of the insulator by being connected to the second pad by a flip-chip method.

5. A method of manufacturing a single-layer board on chip package substrate, the method comprising:
forming a through-hole in an insulator;
stacking a metal layer on an upper surface of the insulator;
forming a first pad and a second pad by selectively etching the metal layer, the first pad covering the through-hole; and
forming a solder resist layer on the upper surface of the insulator in such a way that at least a portion of the second pad is exposed.

6. The method of claim 5, further comprising:
coating a first surface treatment layer on a surface of the first pad, the first pad being exposed through the through-hole; and
coating a second surface treatment layer on a surface of the second pad.

7. The method of claim 6, wherein the coating of the first surface treatment layer comprises injecting a conductive paste into the through-hole so as to fill a portion of the through-hole.

8. The method of claim 5, further comprising:
adhering a solder ball in such a way that the solder ball is connected to a lower surface of the first pad; and
mounting an electronic component on an upper side of the insulator in such a way that the electronic component is connected to the second pad by a flip-chip method.
